(19) United States
(12) Patent Application Publication
(10) Pub. No.: US 2017/0069697 A1
(43) Pub. Date: Mar. 9, 2017

(54) ORGANIC EL DISPLAY PANEL AND ORGANIC EL DISPLAY DEVICE

(71) Applicant: JOLED INC., Tokyo (JP)

(72) Inventors: Jun HASHIMOTO, Tokyo (JP); Hirotaka NANNO, Tokyo (JP); Masakazu TAKATA, Tokyo (JP)

(73) Assignee: JOLED INC., Tokyo (JP)

(21) Appl. No.: 15/309,238

(22) PCT Filed: May 21, 2015
(86) PCT No.: PCT/JP2015/002560

§ 371 Date: Nov. 7, 2016

(30) Foreign Application Priority Data
May 23, 2014 (JP) 2014-107375

(51) Int. Cl. H01L 27/32

(52) U.S. Cl. CPC H01L 27/3246; H01L 27/3218; H01L 27/3216; H01L 2227/323

(57) ABSTRACT

In an organic EL display panel: banks that each extend in the column direction are disposed above a substrate; and red organic light-emitting layers, green organic light-emitting layers, and blue organic light-emitting layers each extend in the column direction and are disposed above the substrate in intervals between adjacent ones of the banks, wherein the banks define edges of sub-pixels of each color in the row direction, and in plan view of the substrate, surface areas of blue sub-pixels are greater than surface areas of red sub-pixels and greater than surface areas of green sub-pixels.

### TECHNICAL FIELD

The present invention relates to organic electroluminescence (EL) elements that use electroluminescence of organic material, organic EL display devices that use the organic EL elements, and in particular to techniques for improving the lifespan of display panels.

### BACKGROUND ART

In recent years, as display panels used in display devices such as televisions, panels have been implemented in which a plurality of organic light-emitting elements are arranged in a matrix on a substrate, using organic EL elements (hereinafter, “organic EL display panels”).

In an organic EL display panel, red, green, and blue organic EL elements form sub-pixels and combinations of red, green, and blue sub-pixels that are next to one another form single pixels. For this organic EL display panel, blue sub-pixels have the shortest lifespan among red, green, and blue sub-pixels, and improving lifespan of blue sub-pixels becomes a technical problem for improving light emission efficiency and lifespan of organic EL elements.

To address this, for example, Patent Literature 1 discloses a technique of pixel configuration such that, in an organic EL display device, light-emitting surface areas of red, green, and blue sub-pixels are 25%, 25%, and 50%, respectively, of a pixel surface area, and therefore luminance half-life of each sub-pixels satisfies a predefined time threshold. Further, Patent Literature 2 discloses an organic EL display device in which there are a plurality of red and a plurality of green sub-pixels for each blue sub-pixel, but a light-emitting surface area of the blue sub-pixel is greater than a light-emitting surface area of the red and green sub-pixels.

### CITATION LIST

### Patent Literature

### [Patent Literature 1] JP 2003-168561

### [Patent Literature 2] JP 2010-3880

### SUMMARY OF INVENTION

### Technical Problem

In the configurations mentioned above, organic light-emitting layers of red, green, and blue sub-pixels are separated by lattice-shaped banks. Thus, when forming organic light-emitting layers during manufacturing of an organic EL display panel, film thickness of organic light-emitting layers may not be uniform across sub-pixels, and therefore further improvement is required in terms of luminance evenness of sub-pixels and reliability.

In view of the above technical problem, the present invention aims to provide an organic EL display panel that is easy to manufacture and contributes to improved lifespan of the organic EL display panel, as well as an organic EL display device using the organic EL display panel.

### Solution to Problem

An organic EL display panel pertaining to an aspect of the present invention is an organic EL display panel in which a plurality of pixels are arranged in a matrix of rows and columns on a substrate, each pixel including a red sub-pixel, a green sub-pixel, and a blue sub-pixel, the organic EL display panel comprising: the substrate; a plurality of banks disposed above the substrate that each extend in a column direction; and a red organic light-emitting layer, a green organic light-emitting layer, and a blue organic light-emitting layer each extending in the column direction and disposed above the substrate in an interval between adjacent ones of the banks, wherein the banks define edges of sub-pixels of each color in a row direction, and in plan view of the substrate, a surface area of the blue sub-pixel is greater than a surface area of the red sub-pixel and greater than a surface area of the green sub-pixel.

### Advantageous Effects of Invention

According to the organic EL display panel pertaining to the above aspect, ink for forming each color of organic light-emitting layer is continuous in the column direction in each interval and therefore even if ink amounts vary in the column direction the ink can flow in the column direction, equalizing film thickness of the organic light-emitting layer, reducing variation in current density of organic light-emitting layers of each sub-pixel, reducing variation in luminance half-life of sub-pixels, and improving life of the panel. Further, an amount of ink applied to bank intervals in which blue organic light-emitting layers are formed is controlled to be greater than an amount of ink applied to bank intervals in which red and green organic light-emitting layers are formed, and therefore width of blue organic light-emitting layers is easily configured to be greater than width of red and green organic light-emitting layers. Thus, manufacture of the organic EL display panel becomes simple, and life of the organic EL display panel is increased.

### BRIEF DESCRIPTION OF DRAWINGS

FIG. 1 is a schematic block diagram showing configuration of a display device 1 pertaining to Embodiment 1.

FIG. 2 is a schematic circuit diagram showing a circuit configuration of each sub-pixel 10a of an organic EL display panel used in the display device 1.

FIG. 3 is a schematic plan view showing a portion of an organic EL display panel pertaining to Embodiment 1.

FIG. 4 is a schematic cross-section through A-A in FIG. 3.

FIG. 5 is a schematic cross-section through B-B in FIG. 3.

FIG. 6A, FIG. 6B, FIG. 6C, and FIG. 6D are schematic cross-sections through A-A showing processes in manufacturing the organic EL display panel.

FIG. 7A, FIG. 7B, FIG. 7C, FIG. 7D, and FIG. 7E are schematic cross-sections through B-B showing processes in manufacturing the organic EL display panel.

FIG. 8A, FIG. 8B, and FIG. 8C show a relationship between interval width of the intervals 20 and luminance half-life of each color of sub-pixel as a rate of change from a reference value for each color; FIG. 8A shows red, FIG. 8B shows green, and FIG. 8C shows blue sub-pixel characteristics.

FIG. 9A and FIG. 9B show experimental results indicating a relationship between applied voltage and current density in the organic EL display panel 10.

FIG. 10 shows experimental results indicating a relationship between an interval width of the intervals 20 and applied voltage to obtain a reference luminance for each color of sub-pixel of the organic EL display panel 10.

FIG. 11 is a schematic diagram of a cross-section of an organic EL display panel 10A pertaining to Modification 1 of Embodiment 1, taken along an identical position to the section B-B in FIG. 3.

### EMBODIMENTS

### Summary of Embodiments

An organic EL display panel pertaining to an aspect of the present invention is an organic EL display panel in which a plurality of pixels are arranged in a matrix of rows and columns on a substrate, each pixel including a red sub-pixel, a green sub-pixel, and a blue sub-pixel, the organic EL display panel comprising: the substrate; a plurality of banks disposed above the substrate that each extend in a column direction; and a red organic light-emitting layer, a green organic light-emitting layer, and a blue organic light-emitting layer each extending in the column direction and disposed above the substrate in an interval between adjacent ones of the banks, wherein the banks define edges of sub-pixels of each color in a row direction, and in plan view of the substrate, a surface area of the blue sub-pixel is greater than a surface area of the red sub-pixel and greater than a surface area of the green sub-pixel.

According to another example, in the row direction, length of the blue sub-pixel is greater than length of the red sub-pixel and greater than length of the green sub-pixel.

According to another example, in the row direction, length of the blue sub-pixel is 1.65 to 3.5 times greater than length of the red sub-pixel.

According to another example, in the row direction, length of the red sub-pixel is 25 μm or greater and length of the blue sub-pixel is less than 170 μm.

According to another example, in the row direction, length of the green sub-pixel is 1.00 to 1.65 times greater than length of the red sub-pixel.

According to another example, a bus is disposed above the substrate, extending in the column direction in a region between pixels that are adjacent to each other in the row direction, the bus being electrically connected to an opposing electrode.

According to another example, a first pixel electrode is disposed above the substrate and below the red organic light-emitting layer; a second pixel electrode is disposed above the substrate and below the green organic light-emitting layer; a third pixel electrode is disposed above the substrate and below the blue organic light-emitting layer; and an opposing electrode that opposes the first pixel electrode, the second pixel electrode, and the third pixel electrode, the opposing electrode is disposed above the red organic light-emitting layer, the green organic light-emitting layer, and the blue organic light-emitting layer.

The organic EL display panel is described above.

A method of manufacturing an organic EL display panel pertaining to an aspect of the present invention is a method of manufacturing the organic EL display panel described above, the method comprising: preparing the substrate; forming the plurality of banks disposed above the substrate that each extend in the column direction; and forming the red organic light-emitting layer, the green organic light-emitting layer, and the blue organic light-emitting layer each extending in the column direction and disposed above the substrate in an interval between adjacent ones of the banks, by applying ink from a plurality of nozzles arrayed in the column direction.

Note that in the present application, “above”, “top”, and “upper” do not refer to an upwards (vertical) direction in absolute spatial awareness, but define relative positional relationships based on an order of layering. Further, “above” is not limited to indicating a relationship between two elements in which a gap is present therebetween, and may be applied when the two elements are in direct contact.

### Embodiment 1

### 1. Configuration of Display Device 1

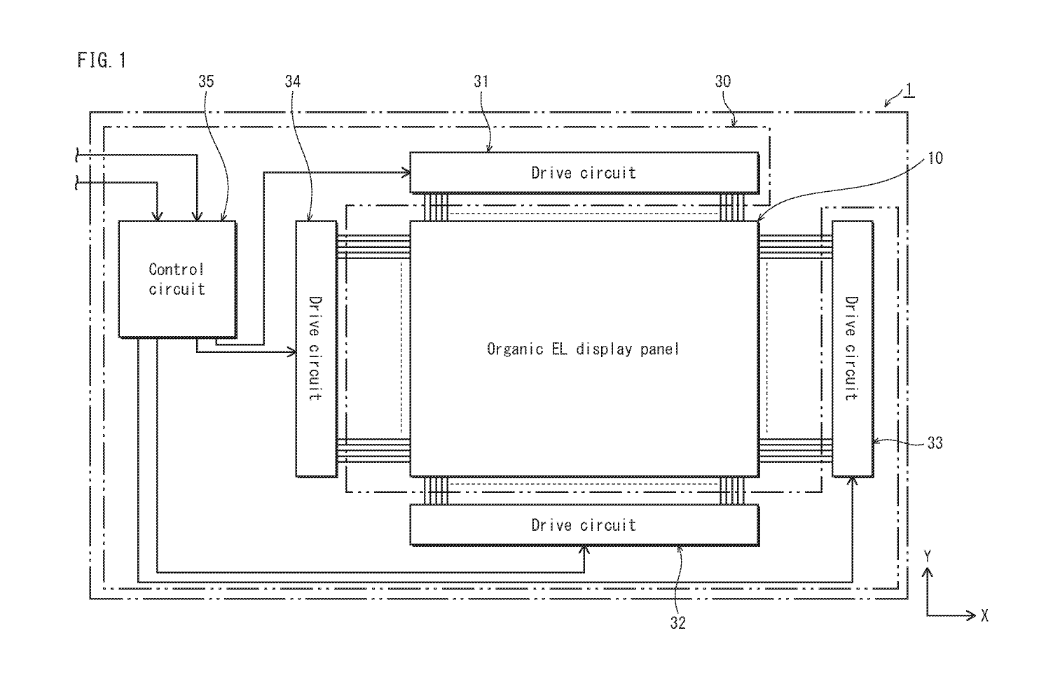

The following describes overall configuration of a display device 1 pertaining to Embodiment 1, with reference to FIG. 1.

As shown in FIG. 1, the display device 1 pertaining to the present embodiment includes an organic EL display panel 10 and drive/control circuitry 30 connected thereto.

The organic EL display panel 10 is an organic electroluminescence (EL) panel that uses electroluminescence of organic material, in which a plurality of organic EL elements are, for example, arranged in a matrix. The drive/control circuitry 30 includes four drive circuits 31, 32, 33, 34 and a control circuit 35.

In the display device 1, the arrangement of the circuits of the drive/control circuitry 30 relative to the organic EL display panel 10 is not limited to the example shown in FIG. 1.

### 2. Circuit Configuration in the Organic EL Display Panel 10

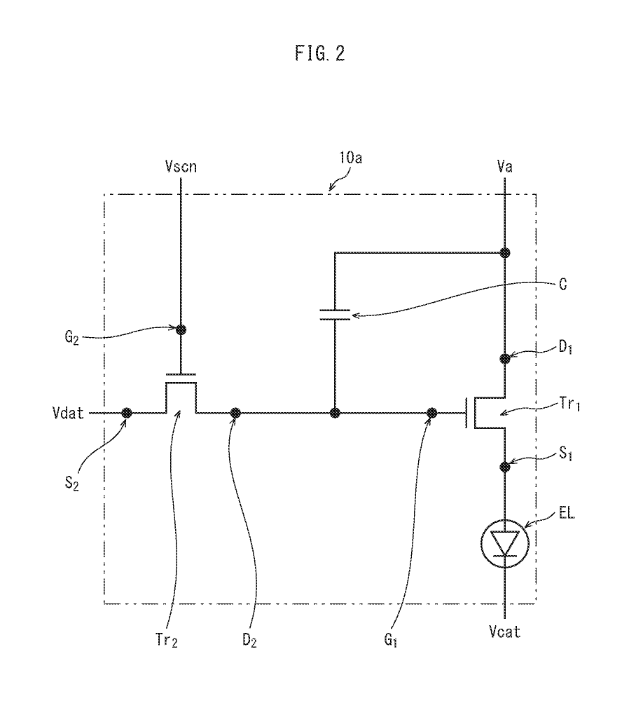

The following describes circuit configuration of each sub-pixel 10a in the organic EL display panel 10, with reference to FIG. 2.

As shown in FIG. 2, according to the organic EL display panel 10 pertaining to the present embodiment, each sub-pixel 10a includes a transistor Tr₁, a transistor Tr₂, a capacitor C, and an EL element EL as a light emitter. The transistor Tr₁ is a drive transistor Tr₁ and the transistor Tr₂ is a switching transistor Tr₂.

A gate G₂ of the switching transistor Tr₂ is connected to a scanning line Vscn and a source S₂ of the switching transistor Tr₂ is connected to a data line Vdat. A drain D₂ of the switching transistor Tr₂ is connected to a gate G₁ of the drive transistor Tr₁.

A drain D₁ of the drive transistor Tr₁ is connected to a power supply line Va and a source S₁ of the drive transistor Tr₁ is connected to an anode of the EL element EL. A cathode of the EL element EL is connected to a ground line Vcat.

The capacitor C connects the drain D₂ of the switching transistor Tr₂, the gate G₁ of the drive transistor Tr₁, and the power supply line Va.

In the organic EL display panel 10, a pixel includes one set of sub-pixels 10a that are adjacent to one another (for example, red (R), green (G), blue (B) sub-pixels 10a), and each pixel is arranged in a matrix to form a pixel region. Each gate line GL extends from a gate G₂ of a pixel arranged in the matrix, and is connected to a scanning line Vscn that is connected from outside the organic EL display panel 10. Similarly, each source line SL extends from a source S₂ of a pixel and is connected to a data line Vdat that is connected from outside the organic EL display panel 10.

Further, power supply lines Va of pixels and ground lines Vcat of pixels are aggregated and connected to a power supply line Va and a ground line Vcat.

### 2. Configuration of Organic EL Display Panel 10

The organic EL display panel 10 pertaining to Embodiment 1, which is an aspect of the present invention, is described below with reference to the drawings. The drawings are schematic, and dimensions may differ from actual implementation.

<Overall Configuration>

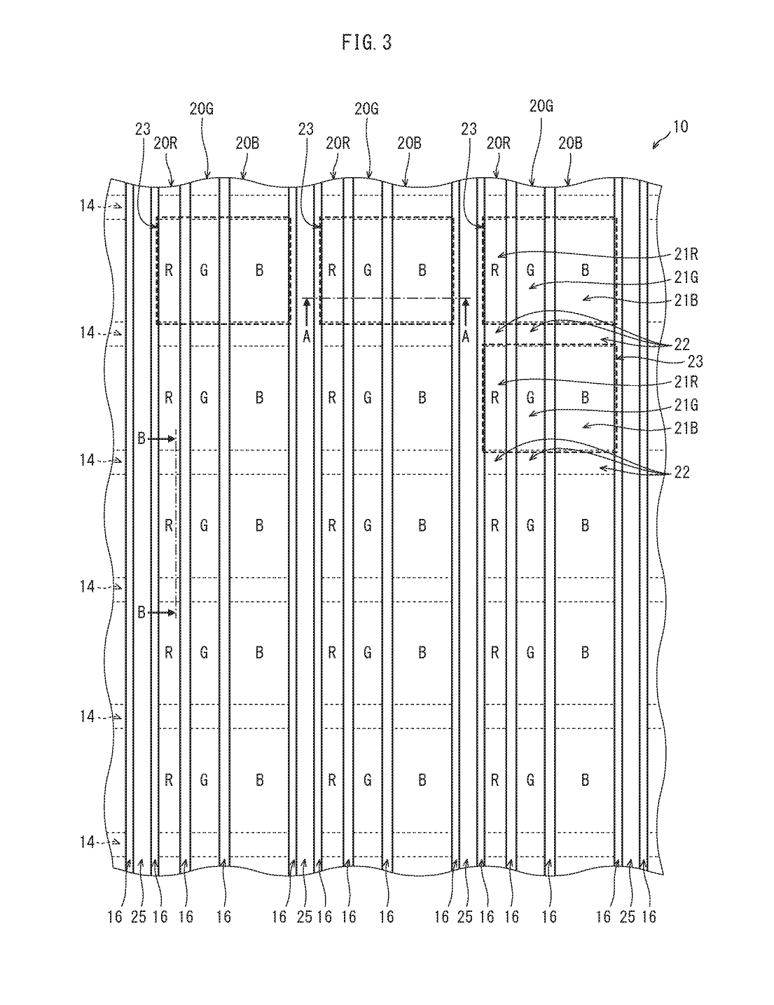

FIG. 3 is a schematic plan view showing a portion of an organic EL display panel pertaining to Embodiment 1. As shown in FIG. 3, the organic EL display panel 10 (hereinafter, “panel 10”) is an organic EL display panel that uses electroluminescence of organic compounds. According to the panel 10, line banks are used, a plurality of first banks 16 extending in a column direction (the top-to-bottom direction of the drawing in FIG. 3). Further, where intervals 20 are defined between adjacent ones of the first banks 16, the panel 10 has a configuration in which the first banks 16 and the intervals 20 alternate.

In each of the intervals 20, a plurality of sub-pixels 21 and a plurality of inter-pixel regions 22 between adjacent ones of the sub-pixel 21 alternate in the column direction. Each of the sub-pixels 21 corresponds to the example of the sub-pixels 10a in FIG. 2. Further, in the inter-pixel regions 22 in the intervals 20 are second banks 14 that extend in a row direction (the left-right direction of the drawing in FIG. 3). The first banks 16 in the column direction and the second banks 14 in the row direction are orthogonal.

According to the present embodiment, the sub-pixels 21 are further classified as red sub-pixels 21R that emit red light, green sub-pixels 21G that emit green light, and blue sub-pixels 21B that emit blue light (where no distinction is made between 21R, 21G, 21B, they are referred to as “sub-pixels 21”). The intervals 20 are further classified as red intervals 20R in which are the red sub-pixels 21R, green intervals 20G in which are the green sub-pixels 21G, blue intervals 20B in which are the blue sub-pixels 21B (where no distinction is made between 20R, 20G, 20B, they are referred to as “intervals 21”). Further, three of the sub-pixels 21, i.e., one of the red sub-pixels 21R, one of the green sub-pixels 21G, and one of the blue sub-pixels 21B, are lined up in the row direction to form one pixel 23.

Edges of the sub-pixels 21 in the column direction are defined by the second banks 14, as described later. The second banks 14 are disposed in the same position in the column direction for each color of the sub-pixels 21. Further, edges of the sub-pixels 21 in the row direction are defined by edges in the row direction of organic light-emitting layers, as described later. The edges in the row direction of the organic light-emitting layers are defined by the first banks 16.

<Configuration>

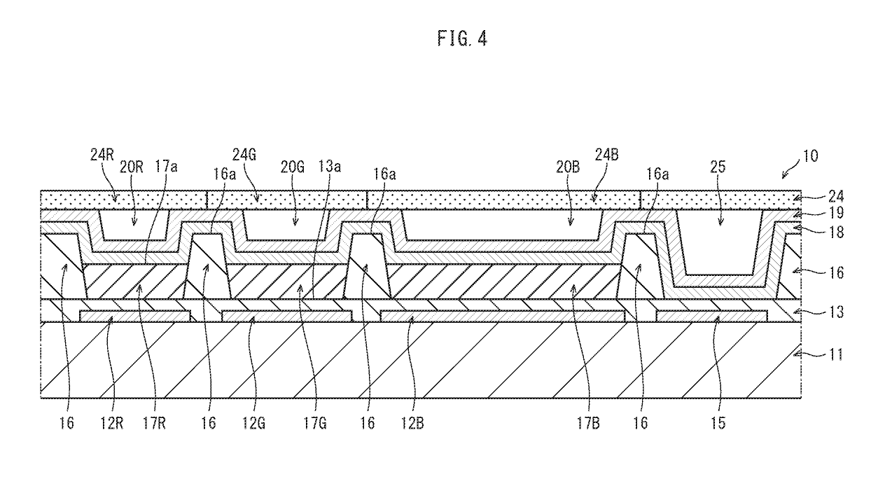

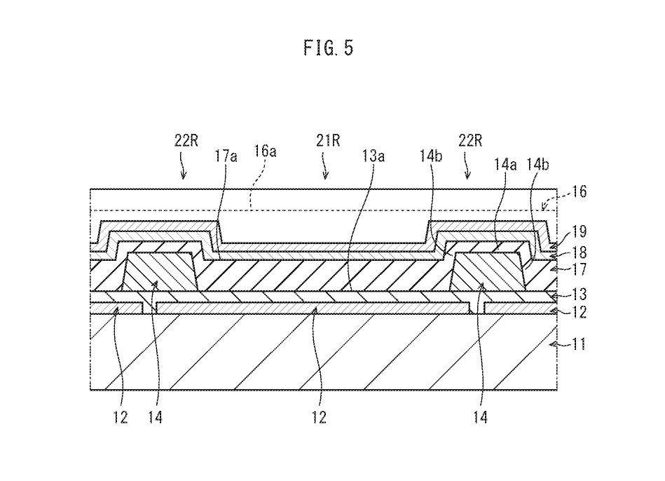

The following describes configuration of the panel 10, with reference to FIG. 4 and FIG. 5. FIG. 4 is a schematic cross-section through A-A in FIG. 3. FIG. 5 is a schematic cross-section through B-B in FIG. 3.

The panel 10, as one example, has a display surface facing a “top side” of the drawings in FIG. 4 and FIG. 5, and is a top-emission type of panel. In the following description, the “top side” of the drawings in FIG. 4 and FIG. 5 is described as the top side of the panel 10.

The panel 10 includes a substrate 11, pixel electrodes 12, a base layer 13, second banks 14, first banks 16, light-emitting layers 17, an opposing electrode 18, and a sealing layer 19.

(1) Substrate

The substrate 11 has a base material (not illustrated), a thin film transistor (TFT) layer (not illustrated) disposed on the base material, and an interlayer insulating layer (not illustrated) disposed on the base material and the TFT layer.

The base material is a supporting material of the panel 10 and is flat. As a material of the base material a material that is electrically insulative can be used, such as a glass material, a resin material, a semiconductor material, or a metal material coated with an insulating layer.

The TFT layer includes a plurality of TFTs and circuitry disposed on a top surface of the base material. Each TFT responds to a drive signal from circuitry external to the panel 10, is electrically connected to a corresponding one of the pixel electrodes 12 and an external power source, and has a layered structure including an electrode, a semiconductor layer, an insulating layer, etc. The circuitry is electrically connected to the TFTs, the pixel electrodes 12, the external power source, the external circuitry, etc.

The interlayer insulating layer planarizes a top surface of the substrate 11 where unevenness is caused by the TFT layer, at least in regions of the sub-pixels 21. Further, the interlayer insulating layer fills between the circuitry and the TFTs, electrically insulating between the circuitry and the TFTs. As a material of the interlayer insulating layer, a positive photosensitive organic material that is electrically insulative can be used, such as acrylic resin, polyimide resin, siloxane resin, or phenolic resin.

(2) Pixel Electrodes

On the substrate 11, first pixel electrodes 12R are disposed in regions of the red sub-pixels 21R, second pixel electrodes 12G are disposed in regions of the green sub-pixels 21G, and third pixel electrodes 12B are disposed in regions of the blue sub-pixels 21B (where no distinction is made between the first pixel electrodes 12R, the second pixel electrodes 12G, and the third pixel electrodes 12B they are referred to as “pixel electrodes 12”). The pixel electrodes 12 supply carriers to the light-emitting layers 17, for example when functioning as anodes they supply holes to the light-emitting layers 17. Each of the pixel electrodes 12 is flat, but, for example, when connection to the TFTs is via contact holes opened in the interlayer insulating layer, each of the pixel electrodes 12 has an uneven shape following the shape of a corresponding contact hole. The pixel electrodes 12 are disposed on the substrate 11 in the intervals 20, spaced from each other in the column direction.

As a material of the pixel electrodes 12, because the panel 10 is a top-emission type, a light-reflective electrically conductive material is preferred, such as a metal like silver, aluminium, or molybdenum, or an alloy thereof.

Further, bus circuitry 15 is disposed on the substrate 11 in an inter-pixel region 25 between pixels that are adjacent in the row direction, the bus circuitry extending in the column direction across the panel 10. The bus circuitry 15 reduces electrical resistance of an opposing electrode 18, described later, and is electrically connected to connected via connected electrodes and the base layer 13. The bus circuitry is made from the same material as the pixel electrodes 12.

(3) Base Layer

The base layer 13 is, for example, a hole injection layer in the present embodiment, and is a continuous solid film above the pixel electrodes 12. When the base layer 13 is formed as a continuous solid film, the manufacturing process is simplified.

Further, the base layer 13 includes a transition metal oxide and functions as a hole injection layer. Here, a transition metal is an element in any group from group 3 to group 11 of the Periodic Table. Among transition metals, transition metals such as tungsten, molybdenum, nickel, titanium, vanadium, chromium, manganese, iron, cobalt, niobium, hafnium, or tantalum are preferred, as they have good hole injection properties after oxidization. In particular, tungsten is suitable for forming a hole injection layer having good hole injection properties. However, the base layer 13 is not limited to being formed from a transition metal oxide, and may for example be an alloy of a transition metal of an oxide other than a transition metal oxide. Further, the base layer 13 is not limited to being a hole injection layer and may be any kind of layer disposed between the pixel electrodes 12 and the light-emitting layers 17.

(4) Second Banks

The second banks 14 control flow of ink in the column direction, the ink being used in forming the light-emitting layers 17 and containing an organic compound that is a material of the light-emitting layers 17. The second banks 14 are present above peripheral portions in the column direction of the pixel electrodes 12 and are formed partially overlapping the pixel electrodes 12 in plan view. Thus, the second banks 14 define edges of the sub-pixels 21 in the column direction. Each of the second banks 14 is elongated in the row direction. In cross-section in the column direction, each of the second banks 14 has a tapered trapezoidal shape that tapers upwards. The second banks 14 extend in the row direction, orthogonal to the column direction, and pass through the first banks 16. Each of the second banks 14 has a top surface 14a that is lower than a top surface 16a of each of the first banks 16.

As a material of the second banks 14, an electrically insulative material is used such as an inorganic material or an organic material. The inorganic material may be silicon oxide or silicon nitride, for example. The organic material may be an acrylic resin, a polyimide resin, a siloxane resin, or a phenolic resin, for example.

(5) First Banks

The first banks 16 control flow of ink in the row direction when forming the light-emitting layers 17 in the intervals 20. The first banks 16 are present above peripheral portions in the row direction of the pixel electrodes 12 and are formed partially overlapping the pixel electrodes 12 in plan view. Thus, the first banks 16 define edges of the sub-pixels 21 in the row direction. Each of the first banks 16 is elongated in the column direction. In cross-section in the row direction, each of the first banks 16 has a tapered trapezoidal shape that tapers upwards. The first banks 16 are disposed on the base layer 13, sandwiching the pixel electrodes 12 in the row direction and passing over the second banks 14.

As a material of the first banks 16, an organic material such as an acrylic resin, a polyimide resin, a siloxane resin, or a phenolic resin can be used, for example. The first banks 16 are preferably formed from a material that is resistant to organic solvents and does not excessively deform or alter in response to etching and baking processes. Further, in order to impart liquid repellency to surfaces of the first banks 16, the surfaces may be fluorine-treated.

Further, the bus circuitry 15 is disposed on the substrate 11 in the inter-pixel region 25 between pixels that are adjacent in the row direction, the bus circuitry extending in the column direction across the panel 10. Here, the inter-pixel region 25 is a region between adjacent pixels in the row direction and indicates an interval external to the adjacent pixels in the row direction.

(6) Light-Emitting Layers

Above the substrate 11, red organic light-emitting layers 17R, green organic light-emitting layers 17G, and blue organic light-emitting layers 17B are disposed along the column direction in the intervals 20 between adjacent ones of the first banks 14 (where no distinction is made between the red organic light-emitting layers 17R, the green organic light-emitting layers 17G, and the blue organic light-emitting layers 17B, they are referred to as “light-emitting layers 17”). The light-emitting layers 17 are layers that include an organic compound and have a function of emitting light by recombination of holes and electrons therein. Each of the light-emitting layers 17 extends in the column direction in one of the intervals 20 and is disposed on a top surface 13a of the base layer 13 in the sub-pixels 21 and on the top surfaces 14a and side surfaces 14b of the second banks 14 in the inter-pixel regions 22.

Only the portions of the light-emitting layers 17 that are supplied carriers from the pixel electrodes 12 emit light. Accordingly, as shown in FIG. 3, only the portions of the light-emitting layers 17 in the sub-pixels 21 over the pixel electrodes 12 emit light, and the portions of the inter-pixel regions 22 on the second banks 14 do not emit light.

As shown in FIG. 3, the light-emitting layers 17 are not only present in the sub-pixels 21 but extend to adjacent ones of the inter-pixel regions 22. Thus, when forming the light-emitting layers 17, ink applied to the sub-pixels 21 can flow in the column direction via ink applied to the inter-pixel regions 22 and film thickness is equalized between the sub-pixels 21 in the column direction. However, in the inter-pixel regions 22, flow of ink is suppressed to an appropriate level by the second banks 14. Accordingly, film thickness unevenness in the column direction is less likely to occur and luminance unevenness of sub-pixels is improved.

Further, an amount of ink applied to bank intervals in which blue organic light-emitting layers are formed is controlled to be greater than an amount of ink applied to bank intervals in which red and green organic light-emitting layers are formed, and therefore width of blue organic light-emitting layers is easily configured to be greater than width of red and green organic light-emitting layers.

As a material of the light-emitting layers 17, an organic material with light-emitting properties that can form a thin film by a wet process is used. For example, a compound, derivative, or complex of a fluorescent material is used, such as an oxinoid compound, perylene compound, coumarin compound, azacoumarin compound, oxazole compound, oxadiazole compound, perinone compound, pyrrolo-pyrrole compound, naphthalene compound, anthracene compound, fluorene compound, fluoranthene compound, tetracene compound, pyrene compound, coronene compound, quinolone compound and azaquinolone compound, pyrazoline derivative and pyrazolone derivative, rhodamine compound, chrysene compound, phenanthrene compound, cyclopentadiene compound, stilbene compound, diphenylquinone compound, styryl compound, butadiene compound, dicyanomethylene pyran compound, dicyanomethylene thiopyran compound, fluorescein compound, pyrylium compound, thiapyrylium compound, selenapyrylium compound, telluropyrylium compound, aromatic aldadiene compound, oligophenylene compound, thioxanthene compound, cyanine compound, acridine compound, metal complex of an 8-hydroxyquinoline compound, metal complex of a 2-bipyridine compound, complex of a Schiff base and a group Ill metal, metal complex of oxine, rare earth complex, or similar (all disclosed in JP H5-163488), or a publicly-known fluorescent material or phosphorescent material is used.

(7) Opposing Electrode

The opposing electrode 18 is disposed above the red organic light-emitting layers 17R, the green organic light-emitting layers 17G, and the blue organic light-emitting layers 17B, and opposes the first pixel electrodes 12R in regions of the red sub-pixels 21R, the second pixel electrodes 12G in regions of the green sub-pixels 21G, and the third pixel electrodes 12B in regions of the blue sub-pixels 21B. The opposing electrode 18 opposes the pixel electrodes 12, forming conductive paths by sandwiching the light-emitting layers 17. The opposing electrode 18 supplies carriers to the light-emitting layers 17, for example when functioning as a cathode it supplies electrons to the light-emitting layers 17. The opposing electrode 18 follows top surfaces 17a of the light-emitting layers 17 and surfaces of the first banks 16 that are exposed from the light-emitting layers 17, forming an electrode common to all the light-emitting layers 17.

As a material of the opposing electrode 18, a light-transmissive electrically-conductive material is used, because the panel 10 is a top-emission type. For example, indium tin oxide (ITO) or indium zinc oxide (IZO) can be used.

The opposing electrode 18 is electrically connected to the bus circuitry 15 via the base layer 13. The bus circuitry is disposed on the substrate 11 in the inter-pixel region 25 between pixels that are adjacent in the row direction, and extends in the column direction. The bus circuitry reduces electrical resistance of the opposing electrode 18.

(8) Sealing Layer

The sealing layer 19 suppresses degradation of the light-emitting layers 17 caused by contact with moisture and air. The sealing layer 19 spans a face of the panel 10, covering a top surface of the opposing electrode 18. As a material of the sealing layer 19, a light-transmissive material is used, such as silicon nitride or silicon oxynitride, because the panel 10 is a top-emission type.

(9) Color Filter, Other

Although not illustrated in FIG. 2 or FIG. 3, a color filter and upper substrate may be joined to the sealing layer 19. Thus, display colors of the panel 10 can be adjusted, stiffness enhanced, and protection from penetration of moisture and air can be provided.

The color filter includes red filters 24R, green filters 24G, and blue filters 24B, disposed above the red intervals 20R, which are regions of the red sub-pixels 21R, the green intervals 20G, which are regions of the green sub-pixels 21G, and the blue intervals 20B, which are regions of the blue intervals 21B.

The color filters 24B, 24G, 24B are light-transmissive layers provided to allow transmission of wavelengths of visible light corresponding to red, green, and blue, and have a function of correcting chromaticity of light emitted from sub-pixels. The color filters 24G, 24R, 24B, for example, are formed by a process of applying ink containing color filter material and solvent to cover glass that is provided with banks in a matrix of rows and columns in which a plurality of openings are provided in units of the sub-pixels 21.

### 2. Organic EL Display Panel Manufacturing Method

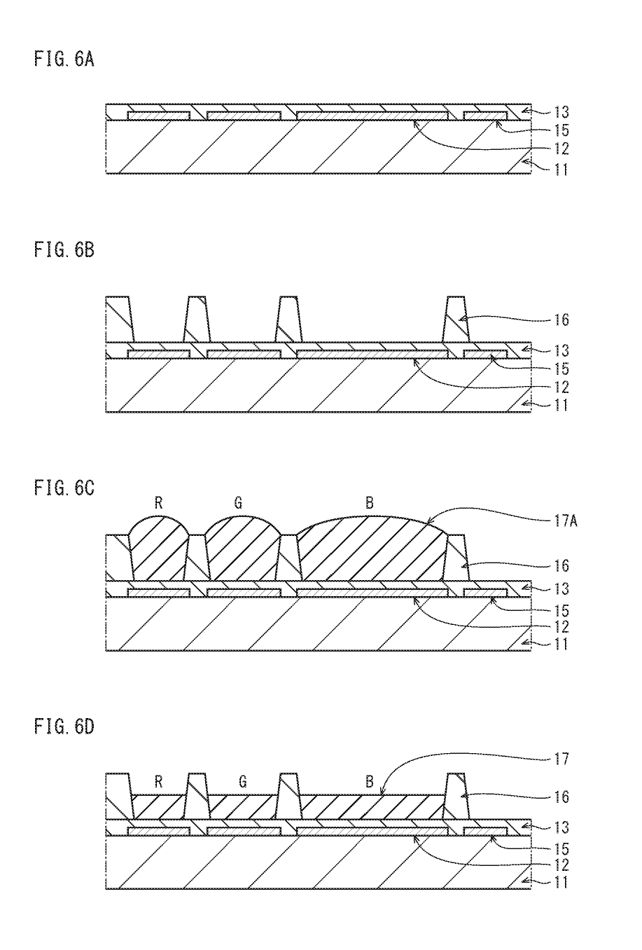

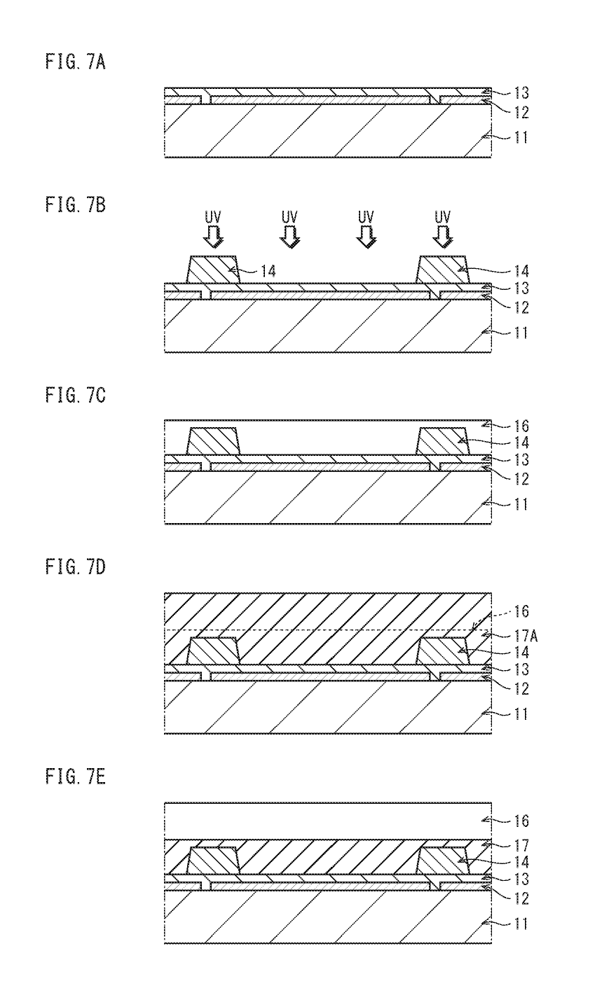

The following describes a method of manufacturing the panel 10, with reference to FIG. 6 and FIG. 7. FIG. 6A, FIG. 6B, FIG. 6C, and FIG. 6D are schematic cross-sections through A-A showing processes in manufacturing the organic EL display panel. FIG. 7A, FIG. 7B, FIG. 7C, FIG. 7D, and FIG. 7E are schematic cross-sections through B-B showing processes in manufacturing the organic EL display panel.

(1) Substrate Preparation Process

First, the substrate 11 is prepared. More specifically, for example, required layers are formed on the base material by a process such as sputtering, chemical vapor deposition (CVD), or spin coating, then patterning is performed by photolithography to form a TFT layer and an interlayer insulating layer. As required, plasma processing, ion injection, baking, etc., may be performed.

(2) Pixel Electrodes Formation Process

Subsequently, the pixel electrodes 12 and the bus circuitry 15 are formed on the substrate 11. More specifically, for example, vacuum deposition or sputtering is used to form a metal film on the substrate 11. Subsequently, the metal film is patterned by photolithography, to form the pixel electrodes 12 at intervals on the substrate 11 in the column direction, and further columns of the pixel electrodes 12 are formed in parallel. In this way, the pixel electrodes 12 are formed in two dimensions on the substrate 11.

(3) Base Layer Formation Process

Subsequently, as shown in FIG. 6A and FIG. 7A, the base layer 13 is formed on the substrate 11 after formation of the pixel electrodes 12. More specifically, for example, a solid film oxide layer (base layer 13) is formed on the substrate 11, completely covering the pixel electrodes 12, by sputtering.

(4) Second Banks Formation Process

Subsequently, as shown in FIG. 7B, the second banks 14 are formed on the base layer 13. More specifically, for example, an inorganic insulating film (such as silicon oxide) is formed on the base layer 13 by CVD. Subsequently, the inorganic insulating film is patterned by photolithography to form the second banks 14, which extend in the row direction and sandwich rows of the pixel electrodes 12.

After forming the second banks 14, the second banks 14 are irradiated from above by UV and then baked, in order to increase lyophilicity.

(5) First Banks Formation Process

Subsequently, as shown in FIG. 6B and FIG. 7C, the first banks 16 are formed on a portion of the base layer 13 and a portion of the second banks 14. More specifically, for example, a positive-type photosensitive organic material (such as acrylic resin) is applied by spin coating. At this time, film thickness of the material applied is greater than film thickness of the second banks 14. Subsequently, the photosensitive organic material is patterned by photolithography to form the first banks 16, which extend in the column direction and sandwich columns of the pixel electrodes 12.

Printing methods, etc., may alternatively be used to directly form the first banks 16. Further, the first banks 16 may be surface treated by alkaline solution, water, organic solvent, or plasma, to confer liquid repellency to surfaces of the first banks 16, the liquid repellency repelling ink applied in a subsequent process. In this way, in a subsequent light-emitting layer formation process, overflow of ink over the first banks 16 is suppressed.

Due to this process, the intervals 20 are formed between adjacent ones of the first banks 16, and columns of the pixels 21 and the inter-pixel regions 22 exist in the intervals 20.

(6) Light-Emitting Layer Formation Process

Subsequently, as shown in FIG. 6C and FIG. 7D, ink 17A is applied in the intervals 20. More specifically, for example, the ink 17A is formed from a mix of an organic compound that will become material of the light-emitting layers 17 and a solvent in a predefined ratio, and the ink 17A is applied in the intervals 20 by using an inkjet method. The ink 17A is applied so that top surfaces of the ink 17A are higher than the top surfaces 14a of the second banks 14, and therefore the ink 17A can flow over the second banks 14. Subsequently, solvent in the ink 17A is evaporated to dryness, thereby forming the light-emitting layers 17. As a method of applying the ink 17A, a dispenser method, nozzle-coating method, spin coating method, or printing method may alternatively be used. In order to prevent the light-emitting layers 17 being divided over the second banks 14, the ink 17A preferably has good wettability with respect to the surfaces of the second banks 14 (the top surfaces 14a and the side surfaces 14b).

Further, according to the present embodiment, the light-emitting layers 17 have the sub-pixels 21 in the three colors red, green, and blue, and therefore different versions of the ink 17A is used for each. More specifically, for example, three colors of the ink 17A may be applied in order using a nozzle that dispenses only the ink 17A corresponding to one of red, green, or blue, or three colors of the ink 17A may be applied simultaneously using three linked nozzles that simultaneously dispense the ink 17A in each of the three colors red, green, and blue.

According to the panel 10, inks of each color of organic light-emitting layer are preferably made from the same material. This is because simultaneously applying the ink simplifies manufacture and contributes to cost reduction. Further, an amount of ink applied to the blue intervals 20B can be controlled to be greater than each amount of ink applied to the red intervals 20R and the green intervals 20G, and therefore length in the row direction of the blue organic light-emitting layers 17B can be easily made longer than length in the row direction of the red organic light-emitting layers 17R and the green organic light-emitting layers 17G. In this case, film thickness in the blue intervals 20B is controlled by setting an amount of ink applied.

Further, because the panel 10 uses line banks, a method of using an array of nozzles in the column direction that each dispense only the ink 17A of the same color while being moved in the row direction orthogonal to the column direction to dispense the ink 17A into the intervals 20 to form the light-emitting layers 17 is preferable. According to this method, a plurality of nozzles are used, which shortens the process and the time to apply the ink 17A. Also, because the ink 17A dispensed from the plurality of nozzles is connected in the column direction in the intervals 20, even if an amount of the ink 17A dispensed from each nozzle varies, the ink 17A can flow in the column direction, which equalizes the amount applied, reducing film thickness unevenness and therefore luminance unevenness between the sub-pixels 21.

Further, due to the decrease in film thickness unevenness, variance in current density of the organic light-emitting layers 17 of each sub-pixel is reduced, variance in luminance half-life of sub-pixels is reduced, and life of the panel 10 is improved. In addition, even when length in the row direction of the sub-pixels 21 is increased to about 130 μm, an increase in leakage current because of a film shape of peripheral portions of the organic light-emitting layers 17 in contact with the first banks 16 being convex can be prevented. Thus, a significant degree of leakage current via the organic light-emitting layers 17 can be prevented.

When the ink 17A is dried, the light-emitting layers 17 are formed in the intervals 20, as shown in FIG. 6D and FIG. 7E. In the intervals 20 are formed the light-emitting layers 17 in the pixels 21 that exist where the second banks 14 do not cover the base layer 13 and across the inter-pixel regions 22 where the second banks 14 are present.

(7) Opposing Electrode Formation Process

Subsequently, the opposing electrode 18 is formed to follow the top surfaces 17a of the light-emitting layers 17 and surfaces of the first banks 16 that are exposed from the light-emitting layers 17. More specifically, for example, a film is formed that is made from a light-transmissive electrically-conductive material such as ITO or IZO, following the top surfaces 17a of the light-emitting layers 17 and surfaces of the first banks 16 that are exposed from the light-emitting layers 17, by a method such as vacuum deposition or sputtering.

At this time, the opposing electrode 18 is also formed in the inter-pixel region 25, which is an interval between pixels that are adjacent to each other in the row direction, between outer banks of the pixels in the row direction. The opposing electrode 18 is electrically connected to the bus circuitry 15, which extends in the column direction in the inter-pixel region 25 on the substrate 11, via the base layer 13.

(8) Sealing Layer Formation Method

Subsequently, the sealing layer 19 is formed covering a top surface of the opposing electrode 18. More specifically, for example, an inorganic insulating film (such as silicon oxide) is formed on the opposing electrode 18 by sputtering or CVD.

### 3. Configuration of Organic EL Display Panel

(1) Ratio of Lengths in Row Direction of Colors of Sub-Pixels 21

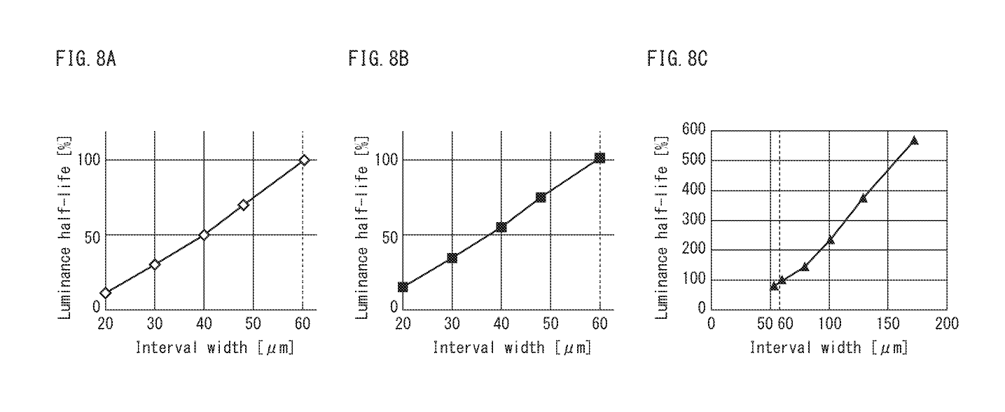

For each color of the sub-pixels in the panel 10, a relationship between length of the sub-pixels 21 in the row direction (interval width of the intervals 20) and luminance half-life of the sub-pixels 21 was investigated. FIG. 8A, FIG. 8B, and FIG. 8C show a relationship between interval width of the intervals 20 and luminance half-life of each color of the sub-pixels 21 as a rate of change from a reference value for each color; FIG. 8A shows red, FIG. 8B shows green, and FIG. 8C shows blue sub-pixel characteristics.

As shown in FIG. 8A, in the red sub-pixels 21R, as interval width is decreased from a reference value of 60 μm to approximately 30 μm, luminance half-life decreases by approximately 30%. Further, as shown in FIG. 8B, in the green sub-pixels 21G, as interval width is decreased from a reference value of 60 μm to approximately 30 μm, luminance half-life decreases by approximately 35%. Further, as shown in FIG. 8C, in the blue sub-pixels 21B, as interval width is increased from a reference value of 60 μm to approximately 130 μm, luminance half-life increases by approximately 380%.

Here, among the three colors of sub-pixels, it is known that red sub-pixels and green sub-pixels have an equal life or green sub-pixels have a shorter life, while blue sub-pixels have a shortest life. Accordingly, by increasing interval width of the blue sub-pixels 21B and decreasing interval width of the red sub-pixels 21R and the green sub-pixels 21G, pixels can be configured to satisfy predetermined times for half-lives of red, green, and blue sub-pixels. Thus, according to the panel 10, in the row direction, length of blue organic light-emitting layers is configured to be greater than length of red organic light-emitting layers and length of green organic light-emitting layers.

More specifically, length of the red organic light-emitting layers that is defined by interval width of the red sub-pixels 21R is preferably 36 μm or greater. This is because, when applying a light-emitting layer by inkjet, a probability that a droplet is accurately dropped into a sub-pixel decreases when interval width is less than 36 μm, from a perspective of droplet landing accuracy. Thus, length of blue organic light-emitting layers, which are defined by interval width of the blue sub-pixels 21B, is preferably from 1.65 (approximately 60 μm) to 3.5 (approximately 130 μm) longer than length of red organic light-emitting layers, which are defined by interval width of the red sub-pixels 21R. In other words, interval width of the blue sub-pixels 21B is preferably 1.65 to 3.5 times greater than interval width of the red sub-pixels 21R.

Further, length of the green organic light-emitting layers is preferably 1.00 (approximately 36 μm) to 1.65 (approximately 60 μm) times greater than length of the red organic light-emitting layers. In other words, interval width of the green sub-pixels 21G is preferably 1.00 to 1.65 times greater than interval width of the red sub-pixels 21R.

As stated above, edges of the sub-pixels 21 in the column direction are defined by the second banks 14. The second banks 14 are disposed in the same position in the column direction for each color of the sub-pixels 21, and therefore length of each color of the sub-pixels is equal in the column direction. Thus, in plan view, surface area of blue sub-pixel regions is greater than surface area of red sub-pixel regions and surface area of green sub-pixel regions.

(2) Upper Limits of Lengths in Row Direction of Sub-Pixels 21

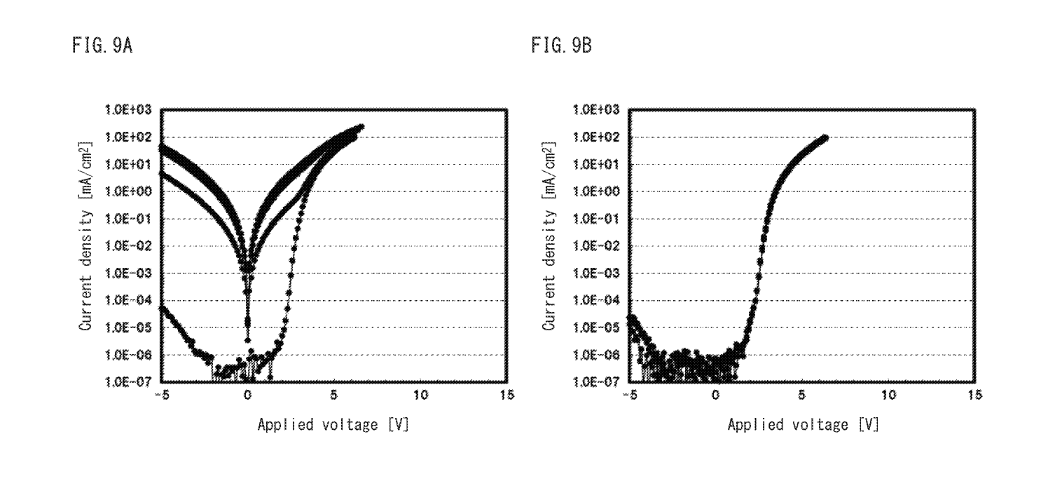

FIG. 9A and FIG. 9B show experimental results indicating a relationship between applied voltage and current density in the panel 10. For the sub-pixels 21 of each color of the panel 10, experimental results show a relationship between applied voltage between the pixel electrodes 12 and the opposing electrode 18 and current density of the organic light-emitting layers 17 when lengths of the sub-pixels 21 in the row direction (interval width of the intervals 20) are 170 μm and 130 μm. FIG. 9A shows current-voltage characteristics (n=5) when interval width is 170 μm, and FIG. 9B shows current-voltage characteristics (n=5) when interval width is 130 μm.

As shown in FIG. 9A, when length of the sub-pixels 21 in the row direction is 170 μm, when applied voltage between the pixel electrodes 12 and the opposing electrode 18 is shifted positively and negatively from 0 V, four out of five data points show a steep increase in current density. In contrast, as shown in FIG. 9B, when length of the sub-pixels 21 is 130 μm, when applied voltage is shifted positively and negatively from 0 V, all five data points show a relatively gentle increase in current density. From these results it can be seen that a significant increase in leakage current via the organic light-emitting layers 17 occurs in the sample for which length of the sub-pixels 21 is 170 μm. It is thought that leakage current increases because a shape of peripheral portions of the organic light-emitting layers 17 in contact with the first banks 16 becomes convex.

Thus, in the row direction, a length of each color of the organic light-emitting layers is preferably less than 170 μm.

(3) Lower Limits of Lengths in Row Direction of Sub-Pixels 21

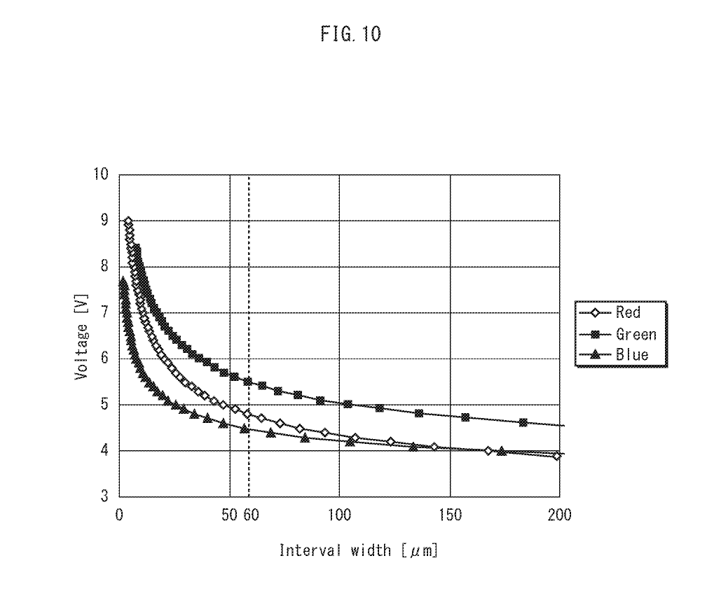

FIG. 10 shows experimental results indicating a relationship between an interval width of the intervals 20 and applied voltage to obtain a reference luminance for each color of sub-pixel of the organic EL display panel 10. As shown in FIG. 10, according to the present embodiment, voltage of green organic light-emitting layers is highest. For example, when interval width of the green organic light-emitting layers is 60 μm, an interval width of less than 25 μm for the red organic light-emitting layers has an applied voltage higher than that of the green organic light-emitting layers. Accordingly, in view of applied voltage, length of organic light-emitting layers is preferably 25 μm or greater.

5. Effects

According to the panel 10, a plurality of the banks 16 are disposed above the substrate 11 that each extend in the column direction; and the red organic light-emitting layers 17R, the green organic light-emitting layers 17G, and the blue organic light-emitting layers 17B each extend in the column direction and are disposed above the substrate 11 in the intervals 20 between adjacent ones of the first banks 16, wherein the first banks 16 define edges of the sub-pixels 21 of each color in the row direction, and in plan view of the substrate 11, surface areas of the blue sub-pixels 21B are greater than surface areas of the red sub-pixels 21R and greater than surface areas of the green sub-pixels 21G. According to another example, in the row direction, length of the blue sub-pixels 21B is greater than length of the red sub-pixels 21R and greater than length of the green sub-pixels 21G.

Thus, ink for forming each color of organic light-emitting layer is continuous in the column direction in each interval and therefore even if ink amounts vary in the column direction the ink can flow in the column direction, equalizing film thickness of the organic light-emitting layer, reducing variation film thickness between the sub-pixels 21, reducing variation in current density of the organic light-emitting layers 17 of sub-pixels, reducing variation in luminance half-life of sub-pixels, and improving life of the panel 10. In addition, even when length in the row direction of the sub-pixels 21 is increased to about 130 μm, an increase in leakage current because of a film shape of peripheral portions of the organic light-emitting layers 17 in contact with the first banks 16 being convex can be prevented. Thus, a significant degree of leakage current via the organic light-emitting layers 17 can be prevented.

Further, film thickness of the organic light-emitting layers is equalized, decreasing film thickness variance between the sub-pixels 21 and therefore decreasing luminance variance.

Further, an amount of ink applied to bank intervals in which blue organic light-emitting layers are formed is controlled to be greater than an amount of ink applied to bank intervals in which red and green organic light-emitting layers are formed, and therefore width of blue organic light-emitting layers is easily configured to be greater than width of red and green organic light-emitting layers. Thus, manufacture of the organic EL display panel becomes simpler, current density is decreased by current reduction in the blue organic light-emitting layers, luminance half-life of the blue organic light-emitting layers is increased, and life of the organic EL display panel can be increased.

<<Modifications>>

The panel pertaining to an aspect of the present invention has been described according to Embodiment 1, but the present invention is not limited to the embodiment described, aside from essential characteristic elements thereof. For example, embodiments that would occur to a person having ordinary skill in the art modifying Embodiment 1, and embodiments implemented by any combination of element and function of Embodiment 1 that does not depart from the scope of the present invention are included in the present invention. The following describes modifications of the panel 10 as examples of such embodiments.

1. Configuration without Second Banks 14

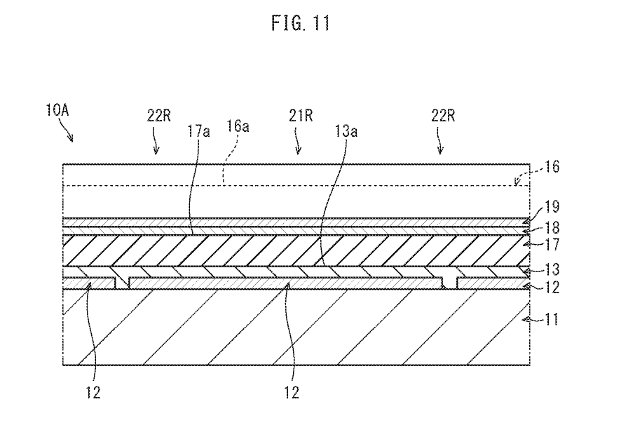

According to the panel 10 pertaining to Embodiment 1, the second banks 14 define edges of the sub-pixel 21 regions in the column direction. However, the panel 10 may be configured without the second banks 14 in the intervals 20. FIG. 11 is a schematic diagram of a cross-section of an organic EL display panel 10A pertaining to Modification 1 of Embodiment 1, taken along an identical position to the section B-B in FIG. 3. As shown in FIG. 11, the second banks 14 are not formed on the top surface 13a of the base layer 13 and only the first banks 16 extend in the column direction above the substrate 11. In this case, edges of the sub-pixel 21 regions in the column direction become edges of the pixel electrodes 12 in the column direction. According to Modification 1, as per Embodiment 1, ink for forming the organic light-emitting layers is connected in the column direction in the intervals, and therefore even if ink amounts vary in the column direction the ink can flow in the column direction, equalizing film thickness of the organic light-emitting layers. Further, variance in current density of the organic light-emitting layers 17 of each sub-pixel is further reduced, variance in luminance half-life of sub-pixels is reduced, and life of the panel 10 is improved.

2. Other Modifications

According to the panel 10 pertaining to Embodiment 1, the filters 25 are above the sub-pixels 21 in the intervals 20. However, the panel 10 may be configured without the filters 24 above the intervals 20.

Further, the present invention is not limited to Embodiment 1. For example, a configuration may be used without using the base layer 13, which is a hole injection layer, in which only the light-emitting layers 17 exist between the pixel electrodes 12 and the opposing electrode 18.

Further, for example, configurations may include hole injection layers, hole transport layers, electron transport layers, or electron injection layers, a plurality of these layers, or all of these layers. Further, these layers need not all be organic compounds, and may be inorganic.

According to Embodiment 1, three types of the sub-pixels 21 are the red sub-pixels 21R, the green sub-pixels 21G, and the blue sub-pixels 21B, but the present invention is not limited to this example. For example, there may be only one type of light-emitting layer, or four types of light-emitting layers may emit red, green, blue, and yellow light.

Further, according to Embodiment 1, the pixels 23 are arranged in a matrix, but the present invention is not limited to this example. For example, even when intervals of pixel regions are one pitch and adjacent ones of the pixel regions are shifted by a half pitch in the column direction, effects of the present invention are achieved. In high definition display panels, it is difficult to visually determine some shift in the column direction, and on a straight line of a certain width (or a zigzag pattern) even uneven film thickness appears to be regular. Accordingly, in such a case, luminance unevenness is suppressed in the zigzag pattern described above, improving display quality of the display panel.

Further, according to Embodiment 1, methods of forming the light-emitting layers 17 are wet film formation processes such as printing, spin coating, and inkjet methods, but the present invention is not limited to these examples. For example, dry film formation processes such as vacuum deposition, electron beam deposition, sputtering, reactive sputtering, ion plating, and vapor phase growth may be used.

Further, according to the panel 10 pertaining to Embodiment 1, the pixel electrodes 12 are disposed in all of the intervals 20, but the present invention is not limited to this configuration. For example, in order to form a bus bar, an interval of the intervals 20 need not have any of the pixel electrodes 12 formed therein.

Further, according to Embodiment 1, the panel 10 is a top-emission type, but a bottom-emission type can alternatively be used. In this case, each configuration is changed as appropriate.

Further, according to Embodiment 1, the panel 10 is configured as an active matrix, but the present invention is not limited to this example and may, for example, by a passive matrix. More specifically, elongated electrodes that extend parallel to the first banks and elongated electrodes that extend orthogonal to the first banks may be provided in plurality, sandwiching the light-emitting layers. When the elongate electrodes that extend orthogonal to the first banks are lower electrodes, a plurality of lower electrodes are arranged in each of the intervals in the direction of extension of the first banks with gaps therebetween, implementing an aspect of the present invention. In this case, each configuration is changed as appropriate. According to Embodiment 1, the substrate 11 has a TFT layer, but in cases such as the passive matrix described above the substrate 11 need not have the TFT layer.

### INDUSTRIAL APPLICABILITY

The organic EL display panel and organic EL display device pertaining to the present invention are applicable to a wide range of devices such as television sets, personal computers, and portable telephones, as well as various other electronic devices that have a display panel.

### REFERENCE SIGNS LIST

1 organic EL display device
10, 10A organic EL display panel
11 substrate
12 pixel electrodes
13 base layer
14 second banks
15 bus circuitry
16 first banks
17 light-emitting layers
18 opposing electrode
19 sealing layer
20 intervals
21 sub-pixel regions
22 inter-pixel regions
23 pixels
24 filters

1. An organic electroluminescence (EL) display panel in which a plurality of pixels are arranged in a matrix of rows and columns on a substrate, each pixel including a red sub-pixel, a green sub-pixel, and a blue sub-pixel, the organic EL display panel comprising:
the substrate;
a plurality of banks disposed above the substrate that each extend in a column direction; and
a red organic light-emitting layer, a green organic light-emitting layer, and a blue organic light-emitting layer each extending in the column direction and disposed above the substrate in an interval between adjacent ones of the banks, wherein
the banks define edges of sub-pixels of each color in a row direction, and
in plan view of the substrate, a surface area of the blue sub-pixel is greater than a surface area of the red sub-pixel and greater than a surface area of the green sub-pixel.

2. The organic EL display panel of claim 1, wherein
in the row direction, length of the blue sub-pixel is greater than length of the red sub-pixel and greater than length of the green sub-pixel.

3. The organic EL display panel of claim 2, wherein
in the row direction, length of the blue sub-pixel is 1.65 to 3.5 times greater than length of the red sub-pixel.

4. The organic EL display panel of claim 3, wherein
in the row direction, length of the red sub-pixel is 25 μm or greater and length of the blue sub-pixel is less than 170 μm.

5. The organic EL display panel of claim 2, wherein
in the row direction, length of the green sub-pixel is 1.00 to 1.65 times greater than length of the red sub-pixel.

6. The organic EL display panel of claim 1, further comprising:
a bus disposed above the substrate, extending in the column direction in a region between pixels that are adjacent to each other in the row direction, the bus being electrically connected to an opposing electrode.

7. The organic EL display panel of claim 1, further comprising:
a first pixel electrode disposed above the substrate and below the red organic light-emitting layer;
a second pixel electrode disposed above the substrate and below the green organic light-emitting layer;
a third pixel electrode disposed above the substrate and below the blue organic light-emitting layer; and
an opposing electrode that opposes the first pixel electrode, the second pixel electrode, and the third pixel electrode, the opposing electrode being disposed above the red organic light-emitting layer, the green organic light-emitting layer, and the blue organic light-emitting layer.

8. A method of manufacturing the organic EL display panel of claim 1, the method comprising:
preparing the substrate;
forming the plurality of banks disposed above the substrate that each extend in the column direction; and
forming the red organic light-emitting layer, the green organic light-emitting layer, and the blue organic light-emitting layer each extending in the column direction and disposed above the substrate in an interval between adjacent ones of the banks, by applying ink from a plurality of nozzles arrayed in the column direction.
